(19) United States
(12) Patent Application Publication
(10) Pub. No.: US 2022/0019286 A1
(43) Pub. Date: Jan. 20, 2022

(54) TOUCH FEEDBACK DEVICE, INTELLIGENT TERMINAL AND VEHICLE

(71) Applicant: JIANGXI OUMAISI MICROELECTRONICS CO., LTD., Nanchang (CN)

(72) Inventor: Chundong XU, Nanchang (CN)

(73) Assignee: JIANGXI OUMAISI MICROELECTRONICS CO., LTD., Nanchang (CN)

(21) Appl. No.: 17/311,309

(22) PCT Filed: Aug. 29, 2019
(86) PCT No.: PCT/CN2019/103355

§ 371 Date: Jun. 4, 2021

(30) Foreign Application Priority Data
Mar. 8, 2019 (CN) 201910176206.2

(51) Int. Cl. G06F 3/01; H01L 41/09; H01L 41/053; G06F 3/041

(52) U.S. Cl. CPC G06F 3/016; H01L 41/09; G06F 2203/04105; G06F 3/0412; H01L 41/053

(57) ABSTRACT

Disclosed is a touch feedback device comprising a touch element, a piezoelectric vibrator (300), a presser detector (700) and a processor. The touch element comprises a frame (100) and a touch screen (200) connected with the frame (100). The piezoelectric vibrator (300) is connected with the touch element, and is used for driving the touch screen (200) to move. The presser detector (700) is connected with the touch element, and is used for detecting the touch pressure applied on the touch screen (200). The processor is connected with the piezoelectric vibrator (300) and the presser detector (700) respectively, and is used for obtaining the touch pressure detected by the presser detector (700) and driving the piezoelectric vibrator (300) to drive, according to the detected touch pressure, the touch screen (200) to generate vibration of a corresponding degree.

### TECHNICAL FIELD

The present disclosure relates to a field of touch feedback technology, and in particular, to a touch feedback device, an intelligent terminal, and a vehicle.

### BACKGROUND

In the related art, a touch feedback device is provided with a vibration generating device configured to perform a tactile feedback to the user's touch through vibration. The tactile feedback refers to a vibration sensation sensed by the user's fingertips when the user touches the touch screen. However, in the current touch feedback device, the extend of the tactile feedback does not vary according to the amount of touch force applied by the user to the touch screen, such that the user experience is poor, which cannot meet the diverse needs of users.

### SUMMARY

Accordingly, it is necessary to provide a touch feedback device, an intelligent terminal, and a vehicle.

A touch feedback device includes:

a touch element comprising a frame and a touch screen connected to the frame;

a piezoelectric vibrator connected to the touch element and configured to drive the touch screen to vibrate;

a pressure detector connected to the touch element and configured to detect a touch pressure applied on the touch screen; and.

a processor connected to the piezoelectric vibrator and the pressure detector, respectively, wherein the processor is configured to obtain the touch pressure detected by the pressure detector, and to drive the piezoelectric vibrator to drive the touch screen to generate a corresponding degree of vibration according to a magnitude of the detected touch pressure.

An intelligent terminal includes:

a terminal body; and

the aforementioned touch feedback device provided in the terminal body.

A vehicle includes:

a central control dashboard; and

the aforementioned touch feedback device provided in the central control dashboard.

### BRIEF DESCRIPTION OF THE DRAWINGS

In order to describe and explain the embodiments and/or examples of the disclosure disclosed herein more clearly, one or more drawings may be referred to. The additional details or examples used to describe the drawings should not be considered as limiting the scope of any of the disclosed disclosures, the described embodiments and/or examples, and the best mode of these disclosures understood.

FIG. 1 is a schematic view of a touch feedback device according to an embodiment of the present disclosure.

FIG. 2 is a cross-sectional view taken along section line II-II of the FIG. 1.

### DETAILED DESCRIPTION OF THE EMBODIMENTS

In order to facilitate the understanding of the present disclosure, the present disclosure will be described more fully with reference to the relevant drawings. The preferred embodiments of the present disclosure are shown in the drawings. However, the present disclosure can be implemented in many forms and is not limited to the embodiments described herein. On the contrary, the purpose of providing these embodiments is to make the disclosure of the disclosure more thorough and comprehensive.

It should be noted that when an element is referred to as being “fixed” or “disposed on” another element, it may be directly on another element or there may also be an intermediate element therebetween. When an element is considered to be “connected” to another element, it may be directly connected to another element or there may be an intermediate element therebetween. As used herein, the terms “inner”, “outer”, “left”, “right”, and similar expressions are for illustration only and are not meant to be the only embodiments.

Unless otherwise defined, all the technical and scientific terms used herein have the same meaning as commonly understood by those skilled in the art. The terms used in the specification of the present disclosure herein are only for the purpose of describing specific embodiments, and are not intended to limit the present disclosure. As used herein, the term “and/or” includes any and all combinations of one or more related mentioned items.

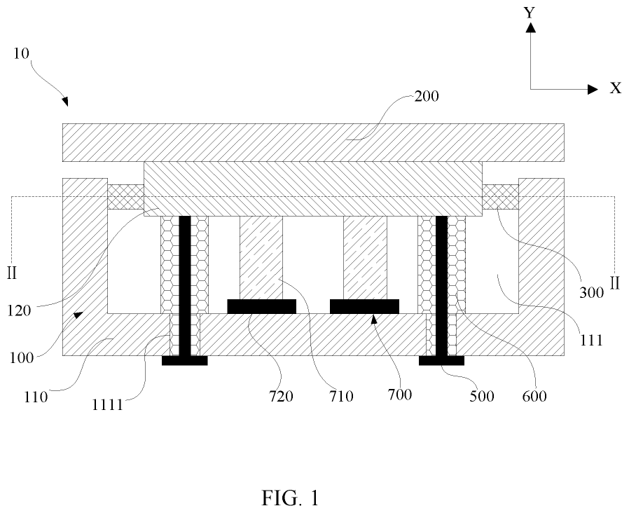

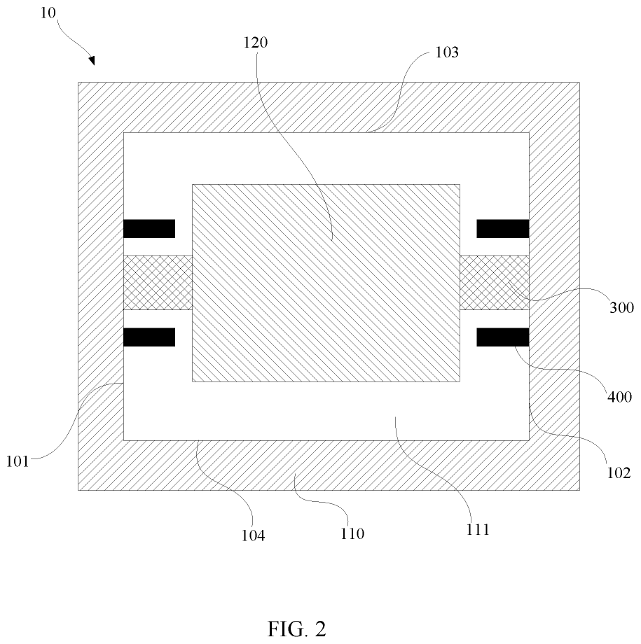

As shown in FIG. 1 and FIG. 2, a touch feedback device 10 of one embodiment of present disclosure can be applied to an intelligent terminal. In one embodiment, the intelligent terminal includes a terminal body and the touch feedback device 10 provided in the terminal body. In one embodiment, the intelligent terminal is a vehicle. For example, the touch feedback device 10 may be mounted in a central control dashboard according to an inner design of the vehicle, such that a user can implement a touch function of the touch feedback device 10 on the central control dashboard of the vehicle. It should be understood that, in other embodiments, the intelligent terminal may be a smart phone, a laptop computer, a tablet computer, a mobile phone, a video phone, a digital still camera, an e-book reader, a portable multi-media player (PMP), a mobile medical device, and a wearable device.

In one embodiment, the touch feedback device 10 includes a touch element and a piezoelectric vibrator 300 connected to the touch element. In one embodiment, the touch element includes a frame 100 and a touch screen 200. The frame 100 is a carrier for the touch screen 200 and the piezoelectric vibrator 300. The frame 100 is also configured to provide a mounting space for the touch screen 200 and the piezoelectric vibrator 300. The touch screen 200 is connected to the frame 100. The touch screen 200 is configured to provide an UI (User Interface), such that the user could perform corresponding touch operations according to a display screen of the touch screen 200. The piezoelectric vibrator 300 is connected to the frame 100. When the user applies a touch pressure to the touch screen 200, the piezoelectric vibrator 300 can provide a vibration force to drive the touch screen 200 to vibrate, so as to implement a tactile feedback when the user touches the touch screen 200. The tactile feedback refers to a vibration sensation of the touch screen 200 sensed by the user's fingertips when the user touches the touch screen 200. The working principle of the piezoelectric vibrator 300 is to use the piezoelectric effect of the material, when the piezoelectric material is energized, the piezoelectric material will be deformed. If a magnitude or direction of the current changes, it will cause different degrees and direction of the deformation, and this deformation is called the vibration. In one embodiment, the piezoelectric vibrator 300 may be a piezoelectric motor. It should be noted that, the manner of driving the touch screen 200 to vibrate may be that the piezoelectric vibrator 300 acts directly on the touch screen 200 to drive the touch screen 200 to vibrate, or the piezoelectric vibrator 300 acts on the frame 100 to drive the touch screen 200 to vibrate. The specific position and the direction of the vibration is not limited and described in detail.

It should be noted that in the touch feedback device 10, when the user touch the touch screen 200, the touch screen 200 senses the user's touch and generates an electric signal, which can be transmitted to a processor of the touch feedback device 10. The processor receives and processes the electric signal, and transmits a corresponding driving signal to the piezoelectric vibrator 300 according to the processed electricity signal, so as to drive the piezoelectric vibrator 300 to drive the touch screen 200 to generate vibration, and hence implement the tactile feedback when the user touches the touch screen 200.

In one embodiment, the frame 100 includes a bottom plate 110 and a support bracket 120. The bottom plate 110 is provided with an accommodation groove 111. The support bracket 120 is provided in the accommodation groove 111 (i.e., the support bracket 120 is connected to a bottom of the accommodation groove 111 via a fastener 500). The touch screen 200 is connected to the support bracket 120. The piezoelectric vibrator 300 is provided between the bottom plate 110 and the support bracket 120. In one embodiment, the piezoelectric vibrator 300 is provided between a sidewall of the accommodation groove 111 and an outer circumferential wall of the support bracket 120. It should be understood that in other embodiments, the piezoelectric vibrator 300 may also be provided between the sidewall of the accommodation groove 111 and an outer circumferential wall of the touch screen 200. As such, the vibration force generated by the piezoelectric vibrator 300 driving the touch screen 200 can be transmitted laterally in a horizontal direction (the horizontal direction could be understood as a direction parallel to an X-axis in FIG. 1). Compared with a vertical transmission of the vibration force in a vertical direction (the vertical direction could be understood as a direction parallel to a Y-axis in FIG. 1) in the prior art, the vibration force of the touch screen 200 is effectively improved, and each region of the touch screen 200 can receive a uniform and stable vibration force. In addition, since the piezoelectric vibrator 300 is provided on the sidewall of the accommodation groove 111, the mounting space of the piezoelectric vibrator 300 in the frame 100 is saved.

It should be noted that, the piezoelectric vibrator 300 and the support bracket 120, or the piezoelectric vibrator 300 and the touch screen 200 may abut against each other in an initial state (i.e., the touch screen 200 is in a non-vibrating state), and may be separated from each other in the initial state. If the two abut against each other in the initial state, the touch feedback of the touch screen 200 occurs once the piezoelectric vibrator 300 vibrates. If the two are separated from each other in the initial state, it is only necessary to ensure that a minimum vibration displacement (a distance of deformation) is greater than a distance between the two.

In one embodiment, there are a plurality of the piezoelectric vibrators 300, which work in series to enhance the vibration intensity of the touch screen 200 and optimize the sensation of the tactile feedback. In addition, the plurality of the piezoelectric vibrators 300 may work independently, in other words, the plurality of the piezoelectric vibrators 300 are driven and controlled by different switch, respectively. Of course, the number of piezoelectric vibrator 300 can be single.

In one embodiment, the sidewall of the accommodation groove 111 includes a first sidewall 101 and a second sidewall 102 that are opposite to each other. The sidewall of the accommodation groove 111 further includes a third sidewall 103 and a fourth sidewall 104 that are opposite to each other. Both ends of the first sidewall 101 are connected to an end of the third sidewall 103 and the fourth sidewall 104, respectively. Both ends of the second sidewall 102 are connected to the other end of the third sidewall 103 and the fourth sidewall 104, respectively. Two piezoelectric vibrators 300 are provided on the first sidewall 101 and the second sidewall 102, respectively. As such, the piezoelectric vibrators 300 located on the first sidewall 101 and the second sidewall 102 are arranged opposite to each other and work cooperatively.

In one embodiment, the touch feedback device 10 includes a limiting buffer member 400 provided between the sidewall of the accommodation groove 111 and the outer circumferential wall of the support bracket 120, and the limiting buffer member 400 is provided on the first sidewall 101 and the second sidewall 102. As such, the limiting buffer member 400 can provide a buffer for a movement of the piezoelectric vibrator 300 in the horizontal direction, thus preventing the touch feedback device 10 from damaging the piezoelectric vibrator 300 due to severe shock under the effect of external factors. For example, when the touch feedback device 10 is applied to the vehicle, it can prevent the piezoelectric vibrator 300 from being damaged by bumping or occasional severe shocks of the vehicle. The limiting buffer element 400 may be a spring or a rubber, etc. In one embodiment, two limiting buffer members 400 are provided on the first sidewall 101, the two limiting buffer members 400 are located on both sides of the piezoelectric vibrator 300, respectively. In addition, two limiting buffer members 400 are provided on the second sidewall 102, the two limiting buffer members 400 are located on both sides of the piezoelectric vibrator 300, respectively.

In one embodiment, the touch feedback device 10 includes a fastener 500. A bottom of the accommodation groove 100 defines a mounting hole 1111, the fastener 500 extends through the mounting hole 1111 and is fixed to the support bracket 120. As such, the fastener 500 can suspend the touch screen 200 and the support bracket 120 as a whole, so as to restrain a movement of the touch screen 200 in a vertical direction, thus preventing the movement deviation in the vertical direction from interfering the vibration of the touch screen 200 in the horizontal direction and improving a user experience. The fastener 500 may be, but not limited to a threaded connecting element such as a screw. It should be noted that that, the fastener 500 does not completely lock the support bracket 120, a fit tolerance between the fastener 500 and the support bracket 120 allows the piezoelectric vibrator 300 to drive the touch screen 200 to slightly deviate in the horizontal direction to generate the vibration feedback.

In one embodiment, the touch feedback device 10 includes an elastic element 600 provided between the support bracket 120 and the bottom of the accommodation groove 111. The elastic element 600 wraps the fastener 500. As such, the elastic element 600 can support and buffer the touch screen 200, thus preventing the touch feedback device 10 from damaging the touch screen 200 due to bumping or severe shocks subjected to a force. The elastic element 600 may be a rubber gasket.

In one embodiment, the touch feedback device 10 includes a pressure detector 700 connected to the touch screen 200. The pressure detector 700 is configured to detect a touch pressure applied on the touch screen 200. In one embodiment, the pressure detector 700 is connected to the touch screen 200 via the support bracket 120. In one embodiment, the pressure detector 700 includes a force transmission block 710 and a pressure sensor 720. The pressure sensor 720 is provided at the bottom of the accommodation groove 111, the force transmission block 710 is provided between the support bracket 120 and the pressure sensor 720, and the pressure sensor 720 is electrically connected to the processor. As such, the touch pressure applied by the user to the touch screen 200 can be detected by the pressure sensor 720 via the force transmission block 710, and transmitted to the processor via the pressure sensor 720.

In the aforementioned touch feedback device 10, when the user applies a touch to the touch screen 200, the pressure detector 700 can detect the touch pressure applied on the touch screen 200, and transmit a detected touch pressure signal to the processor. The processor can classify the detected touch pressure, and drive the piezoelectric vibrator 300 to drive the touch screen 200 to generate corresponding degree of vibration according to the classification of the detected touch pressure (i.e., the greater the touch pressure value, the higher degree of the vibration), thus improving the user experience and satisfying user's diversified use demand.

In the description of the present disclosure, descriptions with reference to the terms “one embodiment”, “some embodiments”, “examples”, “specific examples”, or “some examples” etc. mean specific features, example, structure, materials or characteristics described are included in at least one embodiment or example of the present disclosure. In the present disclosure, the schematic representations of the above terms do not necessarily refer to the same embodiment or example. In addition, the described specific features, structures, materials or characteristics can be combined in any one or more embodiments or examples in a suitable manner. In addition, those skilled in the art can combine the different embodiments or examples and the features of the different embodiments or examples described in the present disclosure without contradicting each other.

The technical features of each embodiment can be combined at an arbitrary. In order to describe in a concise way, not all the possible combinations of the technical features of the above embodiments are described. However, they should be considered within the scope of the present disclosure, as long as the combination of these technical features is in no contradiction.

Although the present disclosure has been described with reference to the embodiments thereof and the best modes for carrying out the present disclosure, it is apparent to those skilled in the art that a variety of modifications and changes may be made without departing from the scope of the present disclosure, which is intend to be defined by the appended claims.

What is claimed is:

1. A touch feedback device, comprising:
a touch element comprising a frame and a touch screen connected to the frame;
a piezoelectric vibrator connected to the touch element and configured to drive the touch screen to vibrate;
a pressure detector connected to the touch element and configured to detect a touch pressure applied on the touch screen; and
a processor connected to the piezoelectric vibrator and the pressure detector, respectively, wherein the processor is configured to obtain the touch pressure detected by the pressure detector, and to drive the piezoelectric vibrator to drive the touch screen to generate a corresponding degree of vibration according to a magnitude of the detected touch pressure.

2. The touch feedback device according to claim 1, wherein the frame comprises a bottom plate defining an accommodation groove and a support bracket provided in the accommodation groove, the touch screen is connected to the support bracket, and the piezoelectric vibrator is provided in the accommodation groove.

3. The touch feedback device according to claim 2, wherein the pressure detector comprises a force transmission block and a pressure sensor, the pressure sensor is provided at a bottom of the accommodation groove, the force transmission block is provided between the support bracket and the pressure sensor, the pressure sensor is electrically connected to the processor.

4. The touch feedback device according to claim 2, wherein the piezoelectric vibrator is provided between a sidewall of the accommodation groove and an outer circumferential wall of the touch screen, the piezoelectric vibrator is configured to drive the touch screen to vibrate in a horizontal direction.

5. The touch feedback device according to claim 2, wherein the piezoelectric vibrator is provided between a sidewall of the accommodation groove and an outer circumferential wall of the support bracket, the piezoelectric vibrator is configured to drive the touch screen to vibrate in a horizontal direction.

6. The touch feedback device according to claim 5, wherein the sidewall of the accommodation groove comprises a first sidewall and a second sidewall that are opposite to each other, further comprises a third sidewall and a fourth sidewall that are opposite to each other, the first sidewall is configured to connect an end of the third sidewall and the fourth sidewall, the second sidewall is configured to connect the other end of the third sidewall and the fourth sidewall, and the piezoelectric vibrator is provided on the first sidewall and the second sidewall.

7. The touch feedback device according to claim 6, further comprising a limiting buffer member provided between the sidewall of the accommodation groove and the outer circumferential wall of the support bracket, and the limiting buffer member is provided on the first sidewall and the second sidewall.

8. The touch feedback device according to claim 7, wherein two limiting buffer members are provided on the first sidewall, the two limiting buffer members are located on both sides of the piezoelectric vibrator, respectively, and two limiting buffer members are provided on the second sidewall, the two limiting buffer members are located on both sides of the piezoelectric vibrator, respectively.

9. The touch feedback device according to claim 7, wherein the limiting buffer member is a spring or a rubber.

10. The touch feedback device according to claim 4, further comprising a fastener, wherein the bottom of the accommodation groove defines a mounting hole, the fastener extends through the mounting hole and is fixed to the support bracket, so as to restrain a movement of the touch screen in a vertical direction.

11. The touch feedback device according to claim 10, wherein the fastener is a threaded connecting element.

12. The touch feedback device according to claim 10, further comprising an elastic element provided between the support bracket and the bottom plate and wrapping the fastener.

13. The touch feedback device according to claim 12, wherein the elastic element is a rubber gasket.

14. An intelligent terminal, comprising:
a terminal body; and
the touch feedback device according to claim 1 provided in the terminal body.

15. A vehicle, comprising:
a central control dashboard; and
the touch feedback device according to claim 1 provided in the central control dashboard.
